(19) United States
(12) Patent Application Publication
(10) Pub. No.: US 2026/0049397 A1
(43) Pub. Date: Feb. 19, 2026

(54) METHOD FOR MANUFACTURING ALUMINUM-DOPED THIN FILM USING 4-COORDINATE ALUMINUM PRECURSOR

(71) Applicant: Samsung Electronics Co., Ltd., Suwon-si (KR)

(72) Inventors: Daeun Kim, Suwon-si (KR); Seung-Min Ryu, Suwon-si (KR); Kazuki Harano, Tokyo (JP); Hiroyuki Uchiuzou, Tokyo (JP); Hitoshi Hosokawa, Tokyo (JP); Ju Seung Kim, Wanju (KR); Yoshiki Manabe, Wanju (KR); Byung Seok Lee, Wanju (KR); Younjoung Cho, Suwon-si (KR); Yu Jin Park, Wanju (KR); Tsubasa Shiratori, Tokyo (JP)

(73) Assignees: SAMSUNG ELECTRONICS CO., LTD., Suwon-si (KR); ADEKA CORPORATION, Tokyo (JP); ADEKA KOREA CORPORATION, Wanju-gun (KR)

(21) Appl. No.: 19/240,661

(22) Filed: Jun. 17, 2025

(30) Foreign Application Priority Data
Aug. 13, 2024 (KR) 10-2024-0108177

(51) Int. Cl. C23C 16/455

(52) U.S. Cl. CPC C23C 16/45553; C23C 16/45534

(57) ABSTRACT

A method for manufacturing an aluminum-doped dielectric film includes supplying a first gas containing an adsorption inhibitor to a substrate, supplying a second gas containing a 4 coordinate aluminum precursor to the substrate, and supplying a third gas containing a reactant, reacting with the 4-coordinate aluminum precursor and the adsorption inhibitor, to the substrate.

### CROSS-REFERENCE TO RELATED APPLICATION(S)

This U.S. non-provisional application claims priority under 35 USC § 119 to Korean Patent Application No. 10-2024-0108177, filed on Aug. 13, 2024, in the Korean Intellectual Property Office, the disclosure of which is herein incorporated by reference in its entirety.

### FIELD OF THE INVENTION

Example embodiments relate to a method for manufacturing an aluminum-doped thin film, and more particularly, to a method for manufacturing a lightly aluminum-doped thin film used in semiconductor devices.

### BACKGROUND

As semiconductor devices continue to shrink, there is growing demand for capacitors having various structures to ensure sufficient capacitance for product operation. To address spatial constraints in capacitor formation, reducing thicknesses of capacitor components has become increasingly important. Accordingly, techniques to reduce thicknesses of thin films used as dielectric films in capacitors have been developed. However, thin films having thicknesses below a certain threshold exhibit non-uniformity and suffer from degradation caused by leakage current, resulting in insufficient capacitance when such a dielectric film is used in capacitors.

### SUMMARY

Example embodiments provide a method for manufacturing a thin film, a dielectric film used in a capacitor of a semiconductor device, having sufficient capacitance while having a uniform small thickness. More specifically, example embodiments provide a method for manufacturing a lightly aluminum-doped thin film used in semiconductor devices.

According to an example embodiment, a method for manufacturing an aluminum-doped dielectric film includes supplying a first gas containing an adsorption inhibitor to a substrate, supplying a second gas containing a 4-coordinate aluminum precursor to the substrate, and supplying a third gas containing a reactant, reacting with the 4-coordinate aluminum precursor and the adsorption inhibitor, to the substrate.

According to an example embodiment, a method for manufacturing a capacitor includes forming a first electrode, forming a second electrode, and forming an aluminum-doped dielectric film between the first electrode and the second electrode. The forming the aluminum-doped dielectric film may comprise supplying a first gas containing an adsorption inhibitor to a substrate on which at least one of the first electrode and the second electrode is formed, supplying a second gas containing a 4-coordinate aluminum precursor to the substrate, and supplying a third gas containing a reactant, reacting with the 4-coordinate aluminum precursor and the adsorption inhibitor, to the substrate.

### BRIEF DESCRIPTION OF DRAWINGS

FIG. 1 is a flowchart showing a method for manufacturing an aluminum-doped dielectric film according to an example embodiment.

FIG. 2 illustrates schematic diagrams illustrating a portion of the method for manufacturing an aluminum-doped dielectric film according to the embodiment illustrated in FIG. 1.

FIG. 3 is a flowchart illustrating a method for manufacturing an aluminum-doped dielectric film according to an example embodiment.

FIG. 4 illustrates schematic diagrams illustrating a portion of a method for manufacturing an aluminum-doped dielectric film according to the embodiment illustrated in FIG. 3.

FIG. 5 is an XPS result graph of Example 4.

FIG. 6 is an XPS result graph of Comparative Example.

### DETAILED DESCRIPTION

While the present disclosure is susceptible to various modifications and alternative forms, specific embodiments thereof are illustrated by way of example in the drawings and will herein be described in detail. However, it should be understood that there is no intent to limit the present disclosure to the particular forms disclosed, but on the contrary, the present disclosure is to cover all modifications, equivalents, and alternatives falling within the spirit and scope of the present disclosure.

While the following terms are believed to be well understood by those skilled in the art, the following definitions are set forth to facilitate description of the presently disclosed subject matter.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in this specification and attached claims are approximations that can vary depending upon the desired properties sought to be obtained by the presently disclosed subject matter. As used herein, the term “about,” when referring to a value or to an amount of mass, weight, time, volume, concentration or percentage is meant to encompass variations of in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed method.

It will be further understood that where features or aspects of the disclosure are described in terms of Markush groups, the disclosure is also intended to be described in terms of any individual member or subgroup of members of the Markush group.

Hereinafter, example embodiments will be described with reference to the accompanying drawings.

An example embodiment relates to a method of forming a thin film used in a semiconductor device by an atomic layer deposition (ALD) process. For example, an example embodiment relates to a method of manufacturing an aluminum-containing thin film using an ALD process. In an example embodiment, the aluminum-containing thin film may be a high-K dielectric film doped with aluminum at a low concentration. A low-concentration aluminum-doped dielectric film may refer to a dielectric film in which an aluminum content is about 0.01 to 15 atomic percent (at %) relative to the total elements in the dielectric film. In an example embodiment, the low concentration aluminum-doped dielectric film may refer to a dielectric film in which an aluminum content is about 0.01 to about 10 at % relative to the total elements of the dielectric film. In an example embodiment, the low concentration aluminum-doped dielectric film may refer to a dielectric film in which an aluminum content is about 0.01 at % to about 7 at % relative to the total elements of the dielectric film.

Hereinafter, an example will be provided in which an aluminum-doped dielectric film is formed when a thin film used in a semiconductor device is formed.

An example embodiment includes a method of doping aluminum while stably controlling a doping concentration of aluminum when a dielectric film is formed. For example, a method of forming the dielectric film uses a specific aluminum precursor to control the doping concentration of aluminum, but may use a reaction inhibiting compound (hereinafter referred to as an “adsorption inhibitor”) forming a final thin film while suppressing adsorption of an aluminum precursor onto a predetermined thin film. This will be described later in detail.

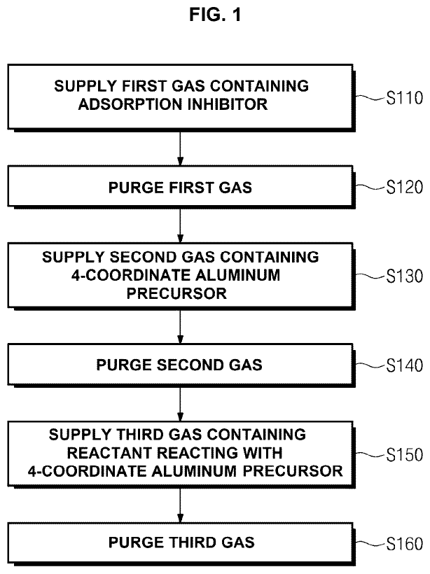

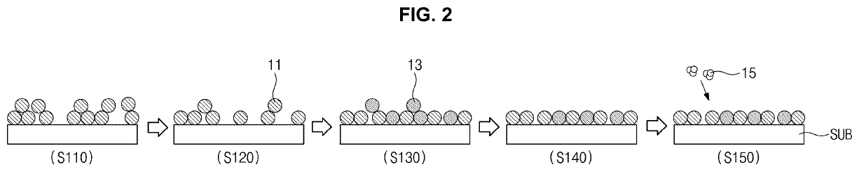

FIG. 1 is a flowchart showing a method for manufacturing an aluminum-doped dielectric film according to an example embodiment. FIG. 2 illustrates schematic diagrams illustrating a portion of the method for manufacturing an aluminum-doped dielectric film according to the embodiment illustrated in FIG. 1.

Referring to FIGS. 1 and 2, an aluminum-doped dielectric film according to an example embodiment may be manufactured by supplying a first gas containing an adsorption inhibitor 11 onto a substrate SUB (S110), purging the first gas (S120), supplying a second gas containing a 4-coordinate aluminum precursor 13 onto the substrate SUB (S130), purging the second gas (S140), supplying a third gas containing a reactant 15 reacting with the 4-coordinate aluminum precursor 13 and the adsorption inhibitor 11 onto the substrate SUB (S150), and purging an unreacted third gas (S160).

A substrate SUB may be prepared. In some embodiments, the substrate SUB may be accommodated in a reaction chamber in which a process for manufacturing a dielectric film is performed.

The substrate SUB may be a substrate SUB for forming a dielectric film on an upper surface thereof. For example, the substrate SUB may be a wafer for manufacturing a semiconductor device. The wafer may comprise, for example, silicon (Si). The wafer may comprise a semiconductor element such as germanium (Ge), or a compound semiconductor such as silicon carbide (SiC), gallium arsenide (GaAs) indium arsenide (InAs), or indium phosphide (InP). According to some embodiments, the wafer may have a silicon-on-insulator (SOI) structure. In some embodiments, the wafer may comprise a buried oxide layer. In some embodiments, the method may comprise a series of processes performed on the wafer. The series of processes may comprise various processes for forming a semiconductor device. The series of processes may comprise, for example, an ion doping process, an oxidation process for forming an oxide layer, a lithography process including spin coating, exposure, and development, a thin film deposition process including chemical vapor deposition (CVD), atomic layer deposition (ALD), physical vapor deposition (PVD), or the like, a dry etching process, a wet etching process, and a metal interconnection process.

A first gas containing an adsorption inhibitor 11 may be supplied onto the substrate SUB. The adsorption inhibitor 11 may be adsorbed onto the substrate SUB to form an adsorption inhibition layer on the substrate SUB. The adsorption inhibition layer may decrease the number of sites to which 4-coordinate aluminum precursors 13 are to be adsorbed.

The adsorption inhibitor 11 may be provided to control the degree and rate of adsorption of a 4-coordinate aluminum precursor 13 to be described later, and to comprise a metal forming a final thin film, for example, a dielectric film. The adsorption inhibitor 11 may react with a material surface in a self-limiting manner to be absorbed to the material surface. The adsorption inhibitor 11 may be selected from compounds having a higher adsorption rate than the 4-coordinate aluminum precursor 13. When the adsorption inhibitor 11 is adsorbed onto a surface of the substrate SUB, even if a 4-coordinate aluminum precursor 13 is provided, the 4-coordinate aluminum precursor 13 may not be adsorbed at a location where the adsorption inhibitor 11 is adsorbed.

The adsorption inhibitor 11 may control an adsorption behavior of the 4-coordinate aluminum precursor 13 to be described later and a deposition rate of the dielectric film based on the reaction with the reactant 15, depending on a surface state of the substrate SUB. The adsorption inhibitor 11 has improved adsorption characteristics, so that surface energy of the substrate SUB may be stabilized when the adsorption inhibitor is adsorbed onto the substrate SUB. As a result, the adsorption inhibitor 11 may inhibit physical adsorption of the 4-coordinate aluminum precursor 13. The adsorption inhibitor 11 blocks sites, in which the 4-coordinate aluminum precursor 13 may be adsorbed, on a surface of the substrate SUB, so that the degree of reaction of a reactant to be described later and a deposition rate of the dielectric film based thereon may be reduced to a desired level.

The adsorption inhibitor 11 according to an example embodiment may include at least one metal compound containing a metal atom. Examples of metal atoms in the adsorption inhibitor 11 may include strontium, barium, scandium, yttrium, lanthanum, titanium, zirconium, hafnium, vanadium, niobium, tantalum, molybdenum, tungsten, manganese, ruthenium, cobalt, nickel, copper, zinc, gallium, indium, tin, or bismuth. In an example embodiment, the metal may be zirconium.

In an example embodiment, the adsorption inhibitor 11 may be provided in the form of a metal complex. In an example embodiment, when the adsorption inhibitor 11 is provided in the form of a metal complex, the metal atom may be easily adsorbed on the surface of the substrate SUB. A ligand in the metal complex or a substituent substituted on the ligand may include a reactive group that is difficult to be adsorbed on the surface of the substrate SUB, and thus may be relatively difficult to be adsorbed on the surface of the substrate SUB compared to the metal atom.

In an example embodiment, the adsorption inhibitor 11 may include at least one compound of a 4-coordinate metal complex of Chemical Formula 8, a 2-coordinate metal complex of Chemical Formula 9, or a 3-coordinate metal complex of Chemical Formula 10.

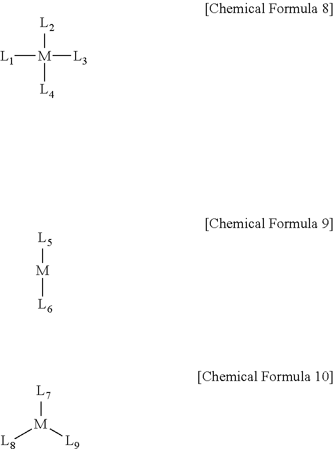

In Chemical Formulas 8 to 10,
M may be strontium, barium, scandium, yttrium, lanthanum, titanium, zirconium, hafnium, vanadium, niobium, tantalum, molybdenum, tungsten, manganese, ruthenium, cobalt, nickel, copper, zinc, gallium, indium, tin, or bismuth, and
L₁ to L₉ may each independently be a halogen atom, *—NR₁R₂, or *—OR₃, or substituted or unsubstituted cyclopentadienyl, where R₁ to R₃ may each independently be a halogen atom or a substituted or unsubstituted C₁ to C₃ alkyl group.

The term “substituted” may refer to substitution by a halogen atom, a halogenated C1 to C3 alkyl group (for example, CCF₃, CHCF₂, CH₂F, CCl₃, or the like), a hydroxyl group, a nitro group, a cyano group, an amino group, an alkylamino group, an amidino group, hydrazine, hydrazone, a sulfonic acid group or salt thereof, a phosphoric acid or salt thereof, or a C1 to C6 alkyl group, a C2 to C6 alkenyl group, a C2 to C6 alkynyl group, a C3 to C6 cycloalkyl group, and the like.

In an example embodiment, at least one compound mentioned in Chemical Formula 11 may be used as the adsorption inhibitor 11.

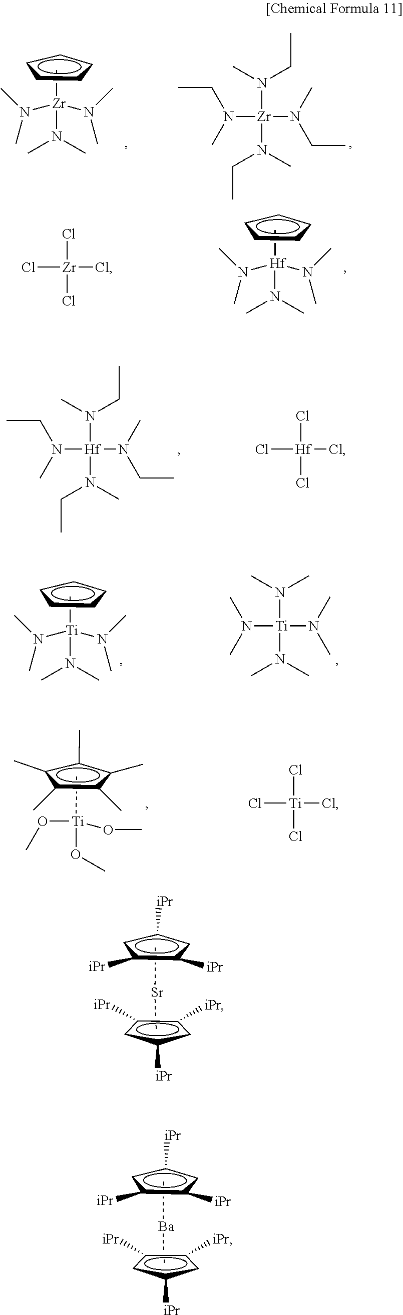

In an example embodiment, the adsorption inhibitor 11 may be a monocyclopentadienyl metal complex having one coordinated cyclopentadienyl ring and at least one polar group. The polar group is a group that is relatively easier to be adsorbed to the surface of the substrate SUB than the cyclopentadienyl ring, and may be a reactive group including a heteroatom such as a nitrogen atom or an oxygen atom. The cyclopentadienyl ring may be a reactive group having a relatively large group compared to the polar group. Accordingly, the cyclopentadienyl ring may provide steric hindrance to prevent other compound molecules from approaching the surface of the substrate SUB. An example of a cyclopentadienyl metal complex used as the adsorption inhibitor 11 is Zr(C₅H₅)(N(CH₃)₂)₃.

A region, in which the adsorption inhibitor 11 is adsorbed on the surface of the substrate SUB, may vary depending on a concentration of the adsorption inhibitor 11 in a first gas, residence time in a reaction chamber, the type of adsorption inhibitor 11, or the like.

In an example embodiment, the first gas may further comprise a carrier gas. The carrier gas may not react with the adsorption inhibitor 11 and may be selected from gases that are not adsorbed to the surface of the substrate SUB. For example, the first gas may further comprise an inert gas such as helium, argon, or nitrogen.

Then, a first purge process may be performed to purge the first gas containing the adsorption inhibitor 11. In the first purge operation, the first gas that is not adsorbed to the surface of the substrate SUB and the first gas that is excessively adsorbed to the surface of the substrate SUB may be purged. For example, among adsorption inhibitor 11 that are physically adsorbed in excess and are multilayered on the surface of the substrate SUB, adsorption inhibitor 11 that are not directly adsorbed to the surface of the substrate SUB may be purged.

The first purge process may be performed by supplying an inert gas to the reaction chamber to discharge unadsorbed first gas present in the chamber. Examples of the inert gas may include helium, argon, or nitrogen.

Then, a second gas containing a 4-coordinate aluminum precursor 13 may be supplied to the surface of the substrate SUB.

The 4-coordinate aluminum precursor 13 may be adsorbed at a location position on the surface of the substrate SUB to which the adsorption inhibitor 11 is not adsorbed. Accordingly, an adsorption inhibition layer may be formed on the substrate SUB. The 4-coordinate aluminum precursor 13 may react with a material surface in a self-limiting manner to be adsorbed on the material surface.

The 4-coordinate aluminum precursor 13 may include at least one compound represented by Chemical Formulas 1 to 7.

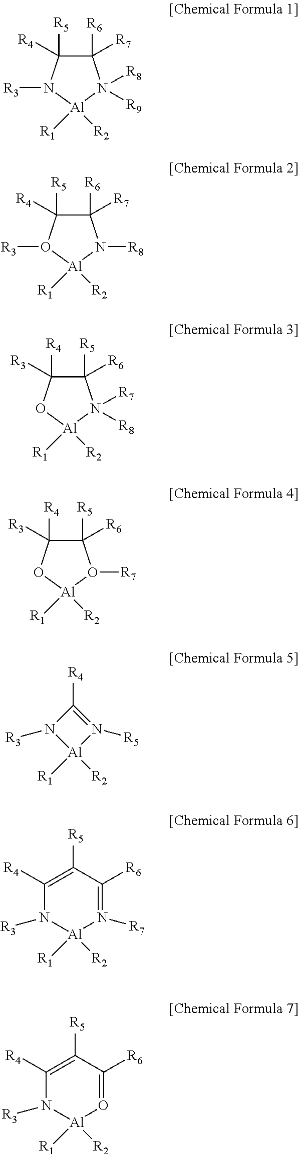

In Chemical Formulas 1 to 7, R₁ to R₉ may each independently be a halogen atom or a substituted or unsubstituted C1 to C5 alkyl group.

In an example embodiment, the 4-coordinate aluminum precursor 13 may be at least one of Al(CH₃)₂(N(tBu)CH₂CH₂N(CH₃)₂), Al(CH₃)₂(N(tC₅H₁₁)CH₂CH₂N(CH₃)₂), or Al(CH₃)₂ (N(tC₈H₁₅)CH₂CH₂N(CH₃)₂).

In an example embodiment, the second gas may further comprise a carrier gas. The carrier gas may not react with the adsorption inhibitor 11 or the 4-coordinate aluminum precursor 13 and may be selected from gases that are not adsorbed to the surface of the substrate SUB. For example, the second gas may further comprise an inert gas such as helium, argon, or nitrogen.

Then, a second purge process may be performed to purge the second gas containing the 4-coordinate aluminum precursor 13. The second purge process may be performed by supplying an inert gas to the reaction chamber to discharge the unadsorbed second gas present therein.

Examples of the inert gas include helium, argon, or nitrogen. In the second purge process, the 4-coordinate aluminum precursor 13 that is not adsorbed to the surface of the substrate SUB may be purged.

A region, in which the 4-coordinate aluminum precursor 13 is adsorbed to the surface of the substrate SUB, may correspond to the remaining region other than the adsorption region of the adsorption inhibitor 11. For example, the wider the adsorption region of the adsorption inhibitor 11 on the surface of the substrate SUB, the narrower the adsorption region of the 4-coordinate aluminum precursor 13. In contrast, the narrower the adsorption region of the adsorption inhibitor 11 on the surface of the substrate SUB, the wider the adsorption region of the 4-coordinate aluminum precursor 13. The degree of adsorption of the 4-coordinate aluminum precursor 13 is related to a doping concentration of aluminum in the dielectric film. For example, when the degree of the adsorption of the 4-coordinate aluminum precursor 13 is low, the doping concentration of aluminum in the dielectric film is low. In addition, when the degree of adsorption of the 4-coordinate aluminum precursor 13 is high, the doping concentration of aluminum in the dielectric film may be high.

Then, a third gas containing a reactant 15 reacting with the 4-coordinate aluminum precursor 13 and the adsorption inhibitor 11 may be provided to the surface of the substrate SUB.

The reactant 15 may react with molecules of the adsorption inhibitor 11 absorbed to the substrate SUB and the 4-coordinate aluminum precursor 13 to oxidize the adsorption inhibitor 11 and the 4-coordinate aluminum precursor 13. Oxidizing the adsorption inhibitor 11 and the 4-coordinate aluminum precursor 13 with the reactant 15 may form a metal-alumina composite oxide layer through an oxidation reaction. The composite oxide layer may be formed as a single layer. The metal may be a metal included in the adsorption inhibitor 11.

The reactant 15 may comprise at least one of oxygen (O₂), ozone (O₃), water vapor (H₂O), hydrogen peroxide (H₂O₂), nitrogen monoxide (NO), nitrous oxide (N₂O), nitrogen dioxide (NO₂), ammonia (NH₃), hydrazine (N₂H₄), amine, diamine, nitrogen (N₂), or hydrogen (H₂). The reactant 15 may react with the 4-coordinate aluminum precursor 13 and/or the adsorption inhibitor 11, and the reaction may end when sites, in which the 4-coordinate aluminum precursor 13 and the adsorption inhibitor 11 may react with the reactant 15, have all reacted. As a result, a content of aluminum may be determined based on the degree of adsorption of the 4-coordinate aluminum precursor 13 on the surface of the substrate SUB.

In an example embodiment, the third gas may further comprise a carrier gas. The carrier gas may not react with the adsorption inhibitor 11 and may be selected from gases that are not adsorbed to the surface of the substrate SUB. For example, the third gas may further comprise an inert gas such as helium, argon, or nitrogen.

Then, a third purge process may be performed to purge the third gas containing the reactant 15. The third purge process may be performed by supplying an inert gas to the reaction chamber to discharge an unadsorbed third gas present in the reaction chamber. Examples of the inert gas include helium, argon, or nitrogen. In the third purge process, a reactive gas that does not react with the 4-coordinate aluminum precursor 13 may be purged.

An operation of supplying the first, second, and third gases to the surface of the substrate SUB and purging each of the gases may constitute a single sequence. In an example embodiment, the sequence may be repeated a plurality of times, and a thickness of the aluminum-doped dielectric film may vary depending on the number of repetitions. In a single sequence, a reactant resulting from the reaction of the 4-coordinate aluminum precursor 13, the adsorption inhibitor 11, and the reactant 15 may be formed as a single atomic layer on the surface of the substrate SUB. As a plurality of sequences are repeated, a plurality of atomic layers may be stacked to increase a thickness of the aluminum-doped dielectric film.

The method of manufacturing an aluminum-doped dielectric film according to an example embodiment may be performed in an order, different from the order in the above-described embodiment.

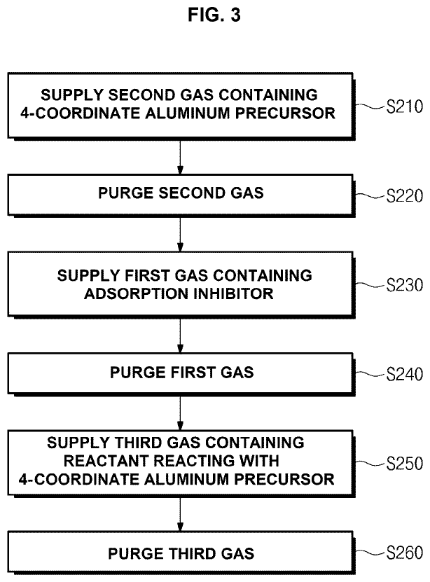

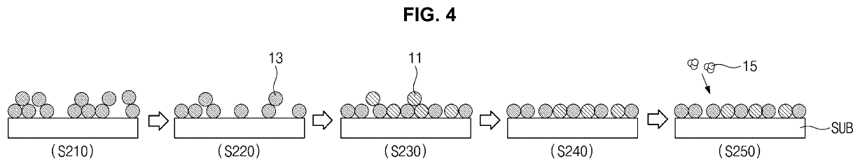

FIG. 3 is a flowchart illustrating a method for manufacturing an aluminum-doped dielectric film according to an example embodiment. FIG. 4 illustrates schematic diagrams illustrating a portion of a method for manufacturing an aluminum-doped dielectric film according to the embodiment illustrated in FIG. 3. In the following embodiments, differences from the above-described embodiment will be mainly described.

Referring to FIGS. 3 and 4, unlike the above-described embodiment, a second gas containing a 4-coordinate aluminum precursor 13 may be supplied to a surface of a substrate SUB (S210), and a first gas containing an adsorption inhibitor 11 may be supplied (S230), and a third gas containing a reactant 15 may be supplied (S250).

For example, an aluminum-doped dielectric film according to an example embodiment may be manufactured by supplying the second gas containing the 4-coordinate aluminum precursor 13 to the surface of the substrate SUB (S210), purging the second gas (S220), supplying the first gas containing the adsorption inhibitor 11 to the substrate SUB (S230), purging the first gas (S240), and supplying the third gas containing the reactant 15 reacting with the 4-coordinate aluminum precursor 13 to the substrate SUB (S250), and purging the unreacted third gas (S260).

Hereinafter, this will be described in detail. The second gas containing the 4-coordinate aluminum precursor 13 may be supplied to the surface of the substrate SUB. The 4-coordinate aluminum precursor 13 may be adsorbed onto the surface of the substrate SUB. A region, in which the 4-coordinate aluminum precursor 13 is adsorbed onto the surface of the substrate SUB, may vary depending on a concentration of the 4-coordinate aluminum precursor 13 in the second gas, residence time in the reaction chamber, and the type of 4-coordinate aluminum precursor 13.

Then, a second purge process may be performed to purge the second gas containing the 4-coordinate aluminum precursor 13. In the second purge process, the 4-coordinate aluminum precursor 13 that is not adsorbed onto the surface of the substrate SUB may be purged. For example, among 4-coordinate aluminum precursors 13 that are physically adsorbed in excess and multilayered on the surface of the substrate SUB, a 4-coordinate precursor that is not directly adsorbed onto the surface of the substrate SUB or is weakly adsorbed onto the surface of the substrate SUB may be purged. As a result, the 4-coordinate aluminum precursor 13 that is physically adsorbed onto the substrate SUB may be purged to decrease a deposition rate of a final dielectric film.

A region, in which the 4-coordinate aluminum precursor 13 is adsorbed onto the substrate SUB, may be adjusted depending on the concentration and speed at which the 4-coordinate aluminum precursor 13 is provided in the reaction chamber. The adsorption region of the adsorption inhibitor 11 to be described later may vary depending on a region in which the 4-coordinate aluminum precursor 13 is adsorbed.

Then, a first gas containing an adsorption inhibitor 11 may be supplied to the substrate SUB. The adsorption inhibitor 11 may be adsorbed onto the substrate SUB and may prevent further adsorption of the 4-coordinate aluminum precursor 13.

The region, in which the adsorption inhibitor 11 is adsorbed onto the surface of the substrate SUB, may correspond to the remaining region other than the adsorption region of the 4-coordinate aluminum precursor 13. For example, the wider the adsorption region of the 4-coordinate aluminum precursor 13 on the surface of the substrate SUB, the narrower the adsorption region of the adsorption inhibitor 11. In contrast, the narrower the adsorption region of the 4-coordinate aluminum precursor 13 on the surface of the substrate SUB, the wider the adsorption region of the adsorption inhibitor 11. For example, the adsorption regions of the 4-coordinate aluminum precursor 13 and the adsorption inhibitor 11 exhibit an inverse relationship. When the adsorption of the 4-coordinate aluminum precursor 13 is low, the doping concentration of aluminum in the dielectric film is low. In addition, when the adsorption of the 4-coordinate aluminum precursor 13 is high, the doping concentration of aluminum in the dielectric film may be high.

Then, a first purge operation may be performed to purge the first gas containing the adsorption inhibitor 11. In the first purge operation, the first gas that is not adsorbed onto the surface of the substrate SUB and the first gas adsorbed in excess on the surface of the substrate SUB may be purged.

Then, a third gas containing a reactant 15 reacting with the 4-coordinate aluminum precursor 13 may be provided to the surface of the substrate SUB.

The reactant 15 may react with molecules of the adsorbed adsorption inhibitor 11 and the 4-coordinate aluminum precursor 13 on the substrate SUB to oxidize at least the aluminum atoms in the 4-coordinate aluminum precursor 13.

Then, a third purge operation may be performed to purge the third gas containing the reactant 15. In the third purge operation, a reactive gas that does not react with the 4-coordinate aluminum precursor 13 may be purged.

An operation of sequentially supplying the second gas, the first gas, and the third gas to the surface of the substrate SUB and purging each of the gases may also constitute a single sequence. In an example embodiment, the sequence may be repeated a plurality of times, and a thickness of the aluminum-doped dielectric film may vary depending on the number of repetitions.

According to an example embodiment, in a single sequence, a reactant resulting from the reaction of the 4-coordinate aluminum precursor 13 and the reactant 15 may be formed as a single atomic layer on the surface of the substrate SUB. Accordingly, in an example embodiment, a dielectric film may be formed with a small number of sequences to obtain a significantly thin and uniform dielectric film.

In addition, according to an example embodiment, when a plurality of sequences are repeated, a plurality of atomic layers may be stacked to obtain an aluminum-doped dielectric film having a large thickness.

In an example embodiment, the amount of the 4-coordinate aluminum precursor 13 adsorbed onto the surface of the substrate SUB may be adjusted depending on whether the first gas or the second gas is first supplied to the surface of the substrate SUB. When the second gas is first supplied to the surface of the substrate SUB, more 4-coordinate aluminum precursors 13 may be adsorbed onto the surface of the substrate SUB than when the first gas is first supplied to the surface of the substrate SUB. In addition, the amount of the 4-coordinate aluminum precursor 13 adsorbed onto the surface of the substrate SUB may be controlled based on a concentration of the adsorption inhibitor 11 and the 4-coordinate aluminum precursor 13 contained in each of the first gas and the second gas, or a flow rate of the first or second gas supplied to the reaction chamber.

In addition, if a sequence of forming a dielectric film by supplying the first gas before the second gas is referred to as a first sequence and a sequence of forming a dielectric film by supplying the second gas before the first gas is referred to as a second sequence, then a process may be performed by combining the first sequence and the second sequence in various forms. For example, a dielectric film may be formed using only the first sequence or only the second sequence. Alternatively, a dielectric film may be formed by alternately combining the first sequence and the second sequence. Alternatively, a dielectric film may be formed by repeating the first sequence a plurality of times and repeating the second sequence a plurality of times.

According to an example embodiment, a dielectric film with a controlled amount of doped aluminum may be formed using the above-described method for manufacturing a dielectric film. For example, a low concentration aluminum-doped dielectric film may be formed using a method for manufacturing a dielectric film according to an example embodiment. Such a low concentration aluminum-doped dielectric film may be formed by using a 4-coordinated aluminum precursor and placing an adsorption inhibitor on the substrate surface. A single atomic layer may be formed per sequence in the aluminum-doped dielectric film, allowing a dielectric film having a significantly small and uniform thickness to be achieved.

According to an example embodiment, in the process of forming an aluminum-doped dielectric film, an adsorption inhibitor compound containing a metal for forming a thin film may be provided before or after adsorbing a relatively bulky 4-coordinate aluminum precursor onto the surface of the substrate, allowing the amount of finally doped aluminum to be controlled. Accordingly, the aluminum-doped dielectric film according to an example embodiment may have a small thickness and low-concentration conformal aluminum doping may be performed, so that a thickness of the dielectric film may be reduced without defects such as leakage current of a capacitor.

In addition, even when an adsorption inhibitor is used, use of a 4-coordinate aluminum precursor may allow for significantly lower concentration aluminum doping than when other aluminum precursors are used. For example, when a 4-coordinate aluminum precursor is used as an aluminum source, the aluminum doping concentration may be significantly reduced to less than half compared to when trimethylaluminum (TMA) is used as an aluminum precursor. An adsorption inhibitor matching the 4-coordinate aluminum precursor may be a compound containing a metal such as zirconium (Zr) or titanium (Ti).

As described above, according to an example embodiment, a low concentration aluminum-doped dielectric film may be formed. The low concentration aluminum-doped dielectric film may be used as a composite layer together with an oxide layer of another material, such as a zirconium oxide layer, and may be used in a capacitor. The aluminum-doped dielectric film may be formed to be uniform with a significantly small thickness, so that the distribution of an aluminum oxide layer in the dielectric film before formation of the capacitor may be increased. As a result, crystallinity of the zirconium oxide layer may be improved and electrical characteristics of the dielectric film may be improved.

According to an example embodiment, the number of repetitions (cycle) of the sequence may be controlled to manufacture a dielectric film having an accurate thickness and a uniform aluminum doping concentration, for example, a low aluminum doping concentration. Therefore, the method for manufacturing the dielectric film according to an example embodiment may be applied to various semiconductor devices requiring a dielectric film. For example, the dielectric film according to an example embodiment may be applied to a high-k gate oxide or a high-k memory capacitor. For example, the aluminum-doped dielectric film according to an example embodiment may be used for a semiconductor device requiring a conformal high-K thin film, for example, a capacitor of a dynamic random access memory (DRAM).

In an example embodiment, a capacitor of a semiconductor device may include a first electrode, a second electrode, and a dielectric film provided between the first electrode and the second electrode. The dielectric film may be manufactured using the above-described method for manufacturing an aluminum-doped dielectric film.

Forming the capacitor of the semiconductor device may include forming a first electrode, forming a second electrode, and forming an aluminum-doped dielectric film between the first electrode and the second electrode.

The formation order and spatial arrangement of the first electrode, the dielectric film, and the second electrode may be changed in various forms. For example, the first electrode may be formed on a substrate, the dielectric film may be formed on the first electrode, and the second electrode may be formed on the dielectric film. Alternatively, the second electrode, the dielectric film, and the first electrode may be sequentially formed. Alternatively, the first electrode and the second electrode may be formed, and the dielectric film may then be formed.

The formation order and spatial arrangement of the first electrode, the dielectric film, and the second electrode may be variously modified based on the structure of the employed semiconductor device.

### Example 1: Preparation of First Compound [AlMe₂(N(tBu)CH₂CH₂NMe₂)]

### 1-1. Preparation Method

Under an argon atmosphere, 132.5 g of a trimethylaluminum hexane solution and 100 g of dehydrated n-hexane were mixed in a 500 ml flask. The mixture was cooled to 5° C., and 42.6 g of N-(tert-butyl)-N′, N′-dimethylethane-1,2-diamine was slowly added dropwise. After the dropwise addition, a temperature was increased to room temperature, and the mixture was stirred for 15 hours. Then, a solvent was removed to obtain a residue. Then, the residue was distilled and purified under a reduced pressure of 500 Pa at a bath temperature of 120° C. to 125° C. As a result, 55 g of a first compound was obtained with a yield of 95%.

### 1-2. Analysis of the First Compound

### (1) Element Analysis (Metal Analysis: ICP-AES)

Al: 8.5% (theoretical value 8.6%), C: 61.2% (theoretical value 61.3%), H: 12.3% (theoretical value 12.2%), N: 18.0% (theoretical value 17.9%)

### (2) 1H-NMR (Solvent: Hexadeuterobenzene) (Chemical Shift: Multiplicity: H Number)

(−0.517: s: 6H), (1.300: s: 9H), (1.689: s: 6H), (2.127 to 2.155: t: 2H), (2.748 to 2.776: t: 2H)

### (3) Atmospheric Pressure TG-DTA

Temperature at 50% mass loss: 149° C. (Ar flow rate: 100 mL/min, heating rate: 10° C./min, sample amount: 9.653 mg)

### Example 2: Preparation of Second Compound [AlMe₂(N(tAm)CH₂CH₂NMe₂)]

### 2-1. Preparation Method

Under an argon atmosphere, 54.7 g of a trimethylaluminum hexane solution and 42 g of dehydrated n-hexane were mixed in a 300 ml flask. The mixture was cooled to 6° C., and 19.1 g of N-(tert-amyl)-N′,N′-dimethylethane-1,2-diamine was slowly added dropwise. After the dropwise addition, a temperature of the mixture was increased to room temperature and the mixture was stirred for 20 hours. Then, a solvent was removed to obtain a residue. Then, the residue was distilled and purified under a reduced pressure of 280 Pa at a bath temperature of 125° C. to 130° C. As a result, 22 g of a second compound was obtained with an 84% yield.

### 2-2. Analysis of Second Compound

### (1) Element Analysis (Metal Analysis: ICP-AES)

Al: 7.9% (theoretical value 7.9%), C: 63.1% (theoretical value 63.3%), H: 12.5% (theoretical value 12.4%), N: 16.4% (theoretical value 16.3%)

### (2) 1H-NMR (Solvent: Hexadeuterobenzene) (Chemical Shift: Multiplicity: H Number)

(−0.513: s: 6H), (0.936 to 0.973: t: 3H), (1.237: s: 6H), (1.471 to 1.527: q: 2H), (1.700: s: 6H), (2.099 to 2.127: t: 2H), (2.619 to 2.648: t: 2H)

### (3) Atmospheric Pressure TG-DTA

Temperature at 50% mass loss: 166° C. (Ar flow rate: 100 mL/min, heating rate: 10° C./min, sample amount: 9.978 mg)

### Example 3: Preparation of Third Compound [AlMe₂(N(tOc)CH₂CH₂NMe₂)]

### 3-1. Preparation Method

Under an argon atmosphere, 31.6 g of a trimethylaluminum hexane solution and 43 g of dehydrated n-hexane were mixed in a 200 ml flask. The mixture was cooled to 9° C., and 13.8 g of N-(tert-octyl)-N′,N′-dimethylethane-1,2-diamine was slowly added dropwise. After the dropwise addition, a temperature of the mixture was increased to room temperature and the mixture was stirred for 14 hours. Then, a solvent was removed to obtain a residue. Then, the residue was distilled and purified under a reduced pressure of 78 Pa at a bath temperature of 95° C. to 105° C. As a result, 14 g of a third compound was obtained with an 81% yield.

### 3-2. Analysis of Third Compound

### (1) Element Analysis (Metal Analysis: ICP-AES)

Al: 6.2% (theoretical value 6.3%), C: 67.7% (theoretical value 67.7%), H: 12.7% (theoretical value 12.8%), N: 13.4% (theoretical value 13.2%)

### (2) 1H-NMR (Solvent: Hexadeuterobenzene) (Chemical Shift: Multiplicity: H Number)

(−0.494: s: 6H), (1.147: s: 9H), (1.371: s: 6H), (1.527: s: 2H), (1.680: s: 6H), (2.093 to 2.121: t: 2H), (2.700 to 2.728: t: 2H)

### (3) Atmospheric Pressure TG-DTA

Temperature at 50% mass loss: 192° C. (Ar flow rate: 100 mL/min, heating rate: 10° C./min, sample amount: 10.343 mg)

### Example 4: Manufacturing of Aluminum-Doped Dielectric Film Using ALD Process

A zirconia-alumina composite oxide layer was formed on a silicon wafer using trisdimethylaminocyclopentadienyl zirconium (Zr(C₅H₅)(N(CH₃)₂)₃) as an adsorption inhibitor and the first compound of Example 1.

An ALD process was performed to form the composite oxide layer. A temperature of a container providing Zr(C₅H₅)(N(CH₃)₂)₃, the adsorption inhibitor, was 80° C., and the temperature of the container for the first compound was 60° C. An ALD process temperature ranges from 200° C. to 350° C. An O₃/O₂ mixed gas was used as a reactive gas.

The following operations (1) to (6) were repeated 50 times as a single cycle to perform the ALD process.
(1) Formation of adsorption inhibition layer: Zr(C₅H₅)(N(CH₃)₂)₃ vaporized using argon was supplied to a reaction chamber at a controlled pressure of 2 hPa for 30 seconds and adsorbed onto a wafer,
(2) First purge: Argon gas was introduced into the reaction chamber for 60 seconds to remove unreacted source materials,
(3) Formation of 4-coordinate aluminum precursor layer: a gas of the first compound vaporized using argon was supplied to the reaction chamber at a controlled pressure of 2 hPa for 30 seconds and adsorbed onto a wafer,
(4) Second purge: Argon gas was introduced into the reaction chamber for 60 seconds to remove unreacted first compound,
(5) Formation of single layer of composite oxide: an O₃/O₂ mixed gas containing 300 g/m³ of O₃ gas was supplied to the reaction chamber and reacted for 60 seconds at 2 hPa to form a single layer of composite oxide, and
(6) Third purge: Argon gas was introduced into the reaction chamber for 30 seconds to remove unreacted reactants.

An aluminum concentration of the zirconia-alumina composite oxide layer obtained by the ALD process was 6 at %, and a carbon content was 0.1 at % or less.

An ideal ALD behavior, where a change in aluminum concentration caused by an increase in wafer temperature is negligible, was exhibited within a wafer temperature range of 200° C. to 350° C.

### Comparative Example

A zirconia-alumina composite oxide layer was formed in the same method as in Example 4, using trimethylaluminum (TMA) instead of the first compound.

An aluminum concentration of the alumina oxide layer obtained by the ALD process was 17 at %, and a carbon content was 0.1 at % or less.

### Evaluation of Example 4 and Comparative Example

Zirconia-alumina composite oxide layers were formed on silicon wafers using the methods described in Example 4 and Comparative Example, respectively. X-ray photoelectron spectroscopy (XPS) was used to analyze a concentration and a composition of each of the composite oxide layers in Example 4 and Comparative Example.

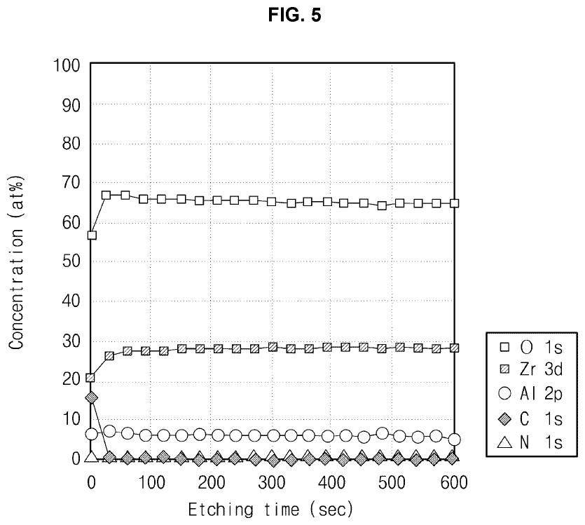

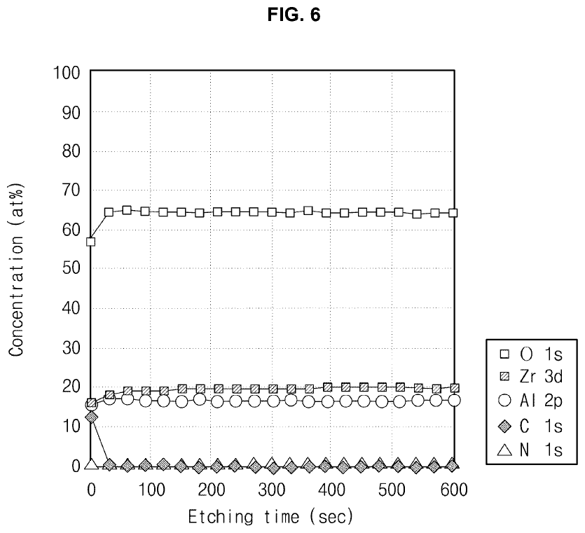

FIG. 5 is an XPS result graph of Example 4, and FIG. 6 is an XPS result graph of Comparative Example. FIGS. 5 and 6 illustrate atomic percentages of O, Zr, Al, C, and N elements obtained through XPS depth profiling.

As illustrated in FIG. 5, the atomic percentage of aluminum in the zirconia-alumina composite oxide layer of Example 4 is only about 6 at %. As illustrated in FIG. 6, the atomic percentage of aluminum in the zirconia-alumina composite oxide layer of Comparative Example is about 17 at %, which is at least twice the atomic percentage of aluminum in Example 4.

This demonstrates that when a thin film is formed by combining an adsorption inhibitor and a 4-coordinate aluminum precursor as described in Example 4, a thin film having a significantly low aluminum doping concentration may be formed.

As set forth above, according to an example embodiment, a method for manufacturing a thin film for a dielectric film having a uniform small thickness and sufficient capacitance may be provided.

In addition, according to an example embodiment, a method for manufacturing a thin film containing a low concentration of aluminum used in a semiconductor device may be provided.

While example embodiments have been shown and described above, it will be apparent to those skilled in the art that modifications and variations could be made without departing from the scope of the present inventive concept as defined by the appended claims.

What is claimed is:

1. A method for manufacturing an aluminum-doped dielectric film, the method comprising:
supplying a first gas comprising an adsorption inhibitor to a substrate;
supplying a second gas comprising a 4-coordinate aluminum precursor to the substrate; and
supplying a third gas comprising a reactant, reacting with the 4-coordinate aluminum precursor and the adsorption inhibitor, to the substrate.

2. The method of claim 1, wherein
the 4-coordinate aluminum precursor comprises at least one compound among compounds represented by Chemical Formulas 1 to 7, 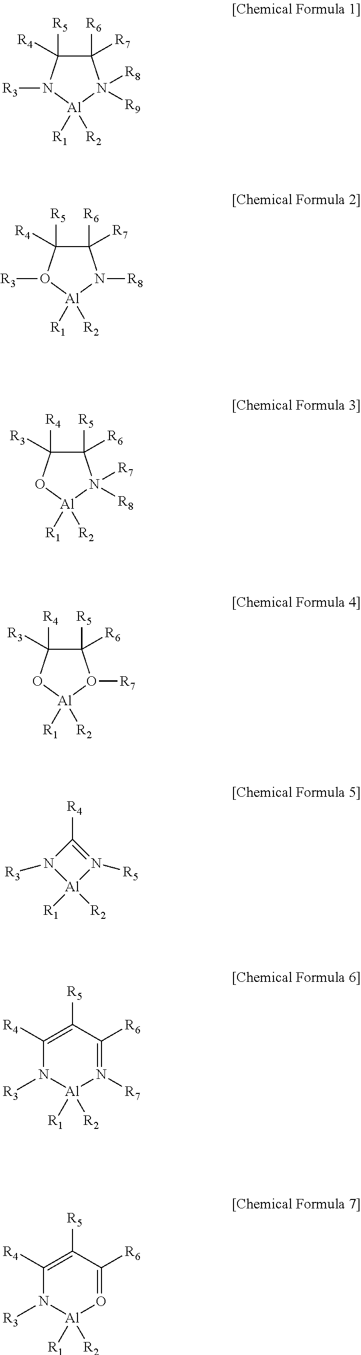
wherein R₁ to R₉ are each independently a halogen atom or a substituted or unsubstituted C1 to C5 alkyl group.

3. The method of claim 2, wherein
the 4-coordinate aluminum precursor is at least one of Al(CH₃)₂(N(tBu)CH₂CH₂N(CH₃)₂), Al(CH₃)₂(N(tC₅H₁₁)CH₂CH₂N(CH₃)₂), or Al(CH₃)₂(N(t CH₁₅)CH₂CH₂N(CH₃)₂).

4. The method of claim 1, wherein
the adsorption inhibitor comprises a metal compound comprising at least one of strontium, barium, scandium, yttrium, lanthanum, titanium, zirconium, hafnium, vanadium, niobium, tantalum, molybdenum, tungsten, manganese, ruthenium, cobalt, nickel, copper, zinc, gallium, indium, tin, or bismuth.

5. The method of claim 4, wherein
the metal compound is provided in a form of a complex.

6. The method of claim 5, wherein
the adsorption inhibitor comprises at least one compound from metal complexes represented by Chemical Formulas 8 to 10, 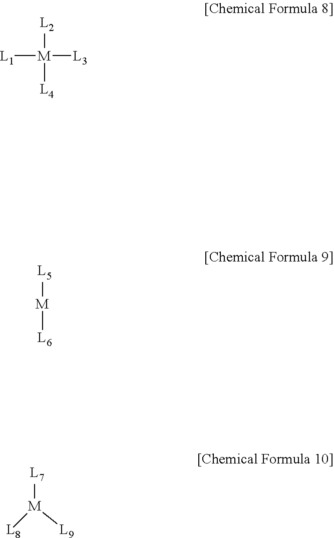
wherein M is strontium, barium, scandium, yttrium, lanthanum, titanium, zirconium, hafnium, vanadium, niobium, tantalum, molybdenum, tungsten, manganese, ruthenium, cobalt, nickel, copper, zinc, gallium, indium, tin, or bismuth, and
L₁ to L₉ are each independently a halogen atom, *—NR₁R₂, or *—OR₃, or substituted or unsubstituted cyclopentadienyl, where R₁ to R₃ are each independently a halogen atom or a substituted or unsubstituted C₁ to C₃ alkyl group.

7. The method of claim 6, wherein
the adsorption inhibitor is at least one compound among compounds represented by Chemical Formula 11

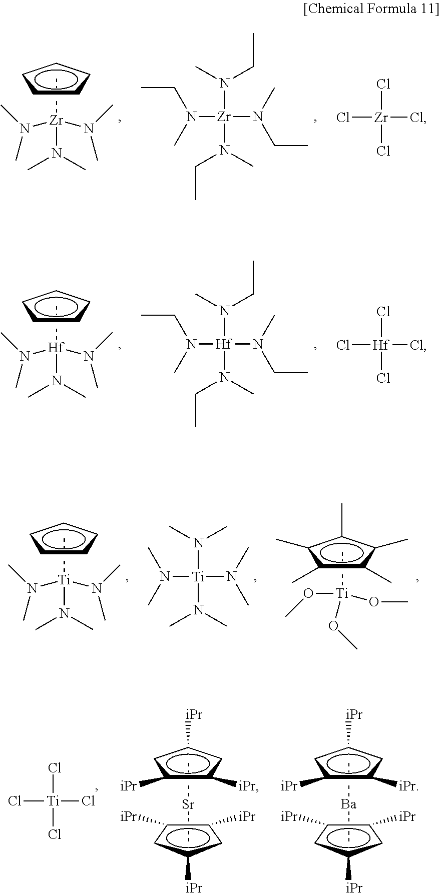

8. The method of claim 7, wherein
the adsorption inhibitor compound is Zr(C₅H₅)(N(CH₃)₂)₃.

9. The method of claim 1, wherein
the reactant comprises at least one of oxygen, ozone, water vapor, hydrogen peroxide, nitrogen monoxide, nitrous oxide, nitrogen dioxide, ammonia, hydrazine, amine, diamine, nitrogen, or hydrogen.

10. The method of claim 9, wherein
the first to third gases comprise argon, helium, or nitrogen as a carrier gas.

11. The method of claim 1, wherein
the dielectric film is manufactured in a reaction chamber accommodating the substrate, and
further comprising:
purging the first gas before supplying the second gas;
purging the second gas before supplying the third gas; and
purging the third gas that has not reacted with the 4-coordinate aluminum precursor.

12. The method of claim 11, wherein
the purging the first gas, the purging the second gas, and the purging the third gas each comprise supplying an inert gas into the reaction chamber.

13. The method of claim 1, wherein
the supplying the first gas is performed before the supplying the second gas is performed.

14. The method of claim 1, wherein
the supplying the second gas is performed before the supplying the first gas is performed.

15. The method of claim 1, wherein
the supplying the first gas, the supplying the second gas, and the supplying the third gas constitute a single sequence, and
the sequence is repeated a plurality of times.

16. A method for manufacturing a capacitor, the method comprising:
forming a first electrode;
forming a second electrode; and
forming an aluminum-doped dielectric film between the first electrode and the second electrode,
wherein
the forming the aluminum-doped dielectric film comprises:
supplying a first gas comprising an adsorption inhibitor to a substrate on which at least one of the first electrode and the second electrode is formed;
supplying a second gas comprising a 4-coordinate aluminum precursor to the substrate; and
supplying a third gas comprising a reactant, reacting with the 4-coordinate aluminum precursor and the adsorption inhibitor, to the substrate.

17. The method of claim 16, wherein
the 4-coordinate aluminum precursor comprises at least one compound among compounds represented by Chemical Formulas 1 to 7, 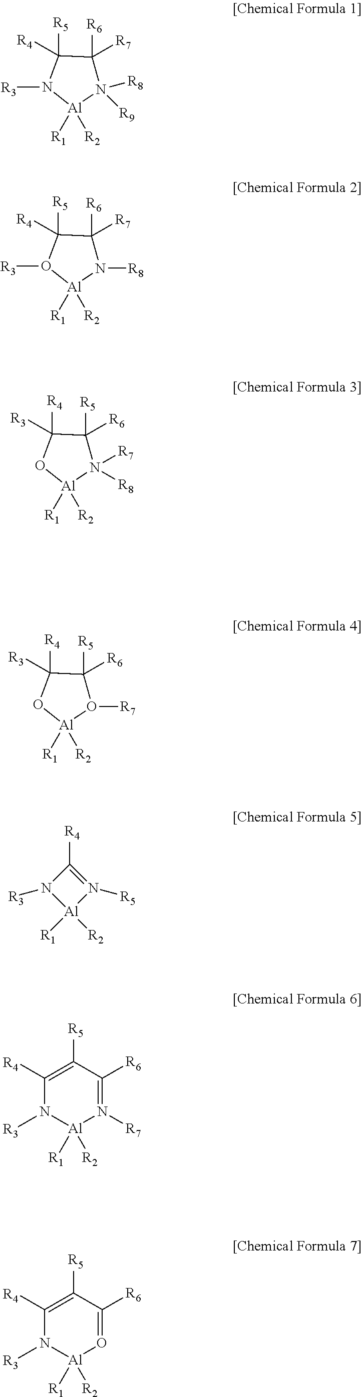
wherein R₁ to R₉ are each independently a halogen atom or a substituted or unsubstituted C1 to C5 alkyl group.

18. The method of claim 17, wherein
the 4-coordinate aluminum precursor is at least one of Al(CH₃)₂ (N(tBu)CH₂CH₂N(CH₃)₂), Al(CH₃)₂(N(tC₅H₁₁)CH₂CH₂N(CH₃)₂), or Al(CH₃)₂(N(t C₈H₁₅)CH₂CH₂N(CH₃)₂), and the adsorption inhibitor is Zr(C₅H₅)(N(CH₃)₂)₃.

19. The method of claim 16, wherein
the adsorption inhibitor comprises at least one metal complex represented by Chemical Formulas 8-10, 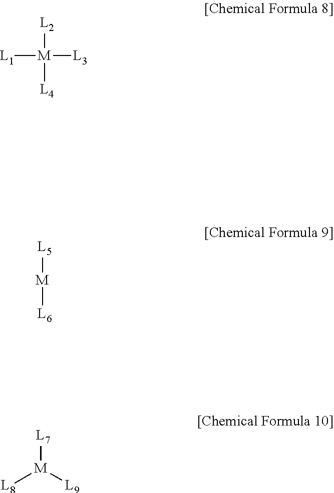
wherein M is strontium, barium, scandium, yttrium, lanthanum, titanium, zirconium, hafnium, vanadium, niobium, tantalum, molybdenum, tungsten, manganese, ruthenium, cobalt, nickel, copper, zinc, gallium, indium, tin, or bismuth, and
L₁ to L₉ are each independently a halogen atom, *—NR₁R₂, or *—OR₃, or substituted or unsubstituted cyclopentadienyl, where R₁ to R₃ are each independently a halogen atom or a substituted or unsubstituted C1 to C3 alkyl group.

20. The method of claim 19, wherein
the adsorption inhibitor is at least one compound among compounds represented by Chemical Formula 11 [chemical structure]
